(19) United States
(12) Patent Application Publication
(10) Pub. No.: US 2015/0342058 A1
(43) Pub. Date: Nov. 26, 2015

(54) METHOD FOR MANUFACTURING HEAT CONDUCTING SUBSTRATE

(71) Applicant: Lighten Corporation, Zhongli City (TW)

(72) Inventor: Cheng-Tao YANG, Zhongli City (TW)

(21) Appl. No.: 14/699,598

(22) Filed: Apr. 29, 2015

(30) Foreign Application Priority Data
May 22, 2014 (TW) 103117857

(51) Int. Cl. H05K 3/00

(52) U.S. Cl. CPC H05K 3/0061

(57) ABSTRACT

A method for manufacturing a heat conducting substrate includes providing a metal plate with a first surface and an opposed second surface; forming a plurality of micro bumps on the first surface; disposing an adhesive layer on the first surface among the micro bumps; providing a circuit layer with a plurality of first openings formed thereon, positions of the first openings corresponding to positions of the micro bumps; fixing the circuit layer onto the adhesive layer, wherein the micro bumps are exposed through the first openings respectively; manufacturing circuits on the circuit layer; and finally, thinning a thickness of the metal plate. The method for manufacturing a heat conducting substrate has the manufactured heat conducting substrate to meet the requirements of being thin-shaped and having high heat conducting electronic elements, and has the advantage of an improved yield.

### BACKGROUND OF THE INVENTION

1. Field of the Invention

The present invention relates to a heat conducting substrate, and particularly to a method for manufacturing a heat conducting substrate which is high heat conducting and thin-shaped.

2. Description of the Prior Art

In the portable electronic products, what is sought by the current consumers is thin-shape and lightweight. However, in the market, because the functionalities of the portable electronic products are expected to be more powerful, the functional electronic elements contained have to be increased correspondingly as well. As the computing speed of the electronic elements becomes faster and the number of the I/O increases, the electronic elements also generate considerable heat during operation. Such heat accumulated in the electronic elements will cause damage to the electronic elements, resulting in the decrease of the lifetime and reliability of the electronic elements.

Currently, the levels and fields where the circuit board is applied are quite broad. All the electronic elements within general electronic products will be inserted into the circuit board. Nowadays, to conform to the high-power and high-heat elements, the circuit board is improved in heat-dissipating.

Therefore, the main developing trend of the industry is a circuit board having a high I/O number, high heat conductivity and an ultra-thin shape.

Currently, the processes of the circuit board are complicated and need various machining processes. To conform to the requirement of thin-shape, if a thinner substrate is directly used in the machining of the circuit board, it is not easy for machining during the machining process because the thickness of the circuit board is too thin. Also, the yield of the circuit board will be decreased and the quality of the electronic products will be impacted.

### SUMMARY OF THE INVENTION

To solve the above-mentioned problems, one objective of the present invention is to provide a method for manufacturing a heat conducting substrate, which has the manufactured heat conducting substrate to meet the requirements of being thin-shaped and having high heat conducting electronic elements.

One objective of the present invention is to provide a method for manufacturing a heat conducting substrate, which performs the adhering and circuit machining processes on a thicker metal plate first and then performs the thinning process to meet the requirements of the electronic elements, so that a prior-art drawback, i.e., a decreased yield, which is resulted from that a thickness of the circuit board is too thin to perform circuit manufacturing, can be avoided.

To achieve the above-mentioned objective, a method for manufacturing a heat conducting substrate of one embodiment of the present invention comprises: providing a metal plate with a first surface and an opposed second surface; forming a plurality of micro bumps on the first surface; disposing an adhesive layer on the first surface among the micro bumps;

providing a circuit layer with a plurality of first openings formed thereon, positions of the first openings corresponding to positions of the micro bumps; fixing the circuit layer on the adhesive layer, wherein the micro bumps are exposed through the first openings respectively; and manufacturing circuits on the circuit layer.

In one embodiment of the present invention, the present invention further comprises a thinning process which is performed on the metal plate from the second surface, wherein the metal plate may be thinned completely so that only the micro bumps are remained.

In one embodiment of the present invention, the metal plate is thinned in a chemical or mechanical manner.

In one embodiment of the present invention, the circuit layer is a copper layer, wherein the adhesive layer and the copper layer are fixed together to be a resin-coated copper (RCC), and a plurality of second openings, which correspond to the first openings respectively, are formed on the adhesive layer, wherein the resin-coated copper is fixed to the first surface of the metal plate by the adhesive layer thereof, and the micro bumps pass through the second openings and the first openings to be exposed. The first openings and the second openings may be formed integrally.

In one embodiment of the present invention, the adhesive layer and the circuit layer are fixed together in a lamination or compression molding manner.

In one embodiment of the present invention, a top surface of the micro bump is flush with a surface of the circuit layer.

In one embodiment of the present invention, a total thickness of the metal plate, the adhesive layer and the circuit layer which are laminated is not more than 30 microns.

The objectives, subject matters and properties of the present invention and the effects achieved by the present invention will become apparent from the following descriptions of the embodiments taken in conjunction with the accompanying drawings.

### BRIEF DESCRIPTION OF THE DRAWINGS

FIG. 1a through FIG. 1d show structural schematic views of a method for manufacturing a heat conducting substrate of a first embodiment of the present invention.

FIG. 2 shows a structural schematic view of a heat conducting substrate manufactured with one embodiment of the present invention.

FIG. 3a through FIG. 3d show structural schematic views of a method for manufacturing a heat conducting substrate of a second embodiment of the present invention.

### DESCRIPTION OF THE PREFERRED EMBODIMENT

Detail descriptions are as follows, and the described preferred embodiments are for illustration and are not used to limit the present invention.

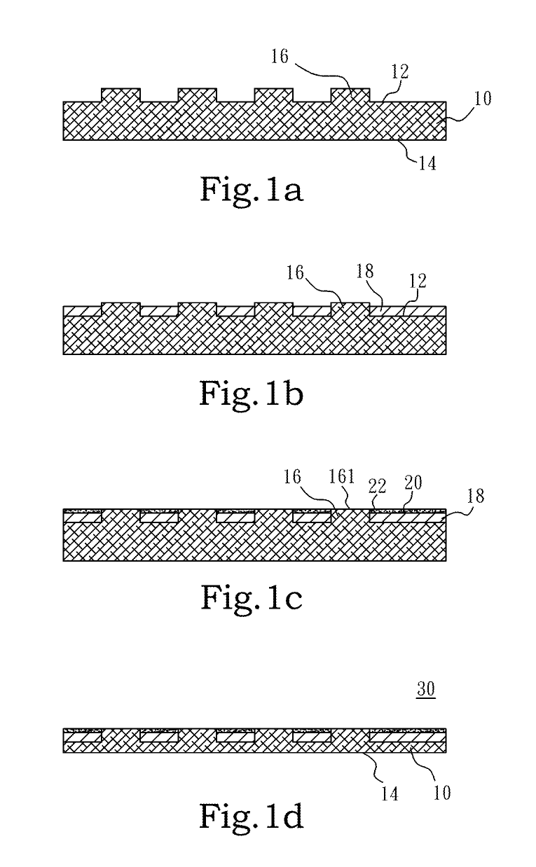

Referring to FIG. 1a through FIG. 1d, FIG. 1a through FIG. 1d show structural schematic views of a method for manufacturing a heat conducting substrate of a first embodiment of the present invention. As shown in FIG. 1a, a metal plate 10 is provided, which has a first surface 12 and an opposed second surface 14. A plurality of micro bumps 16 are formed on the first surface 12. Then, as shown in FIG. 1b, an adhesive layer 18 is coated on the first surface 12 where no micro bumps 16 are formed, so that the adhesive layer 18 is among the micro bumps 16. In one embodiment, a thickness of the adhesive layer 18 is slightly less than a height of the micro bumps 16. Then, as shown in FIG. 1c, a circuit layer 20 is provided with a plurality of first openings 22 formed thereon, and positions of the first openings 22 corresponds to positions of the micro bumps 16. The circuit layer 20 is fixed onto the adhesive layer 18, and top surfaces 161 of the micro bumps 16 are exposed through the first openings 22. In one embodiment, top surfaces 161 of the micro bumps 16 are flush with a surface of the circuit layer 20. Then, circuits are manufactured on the circuit layer 20 (not shown). Finally, a thinning process is performed. As shown in FIG. 1d, the metal plate 10 is thinned from the second surface 14 of the metal plate 10. As such, a heat conducting substrate structure 30 is completed.

In one embodiment, the circuit layer 20 is a copper layer. The adhesive layer 18 and the circuit layer 20 are fixed together in a lamination or compression molding manner. The respective thicknesses of the adhesive layer 18 and the circuit layer 20 are thinned to a micron (um) level, and a total thickness of the metal plate 10, the adhesive layer 18 and the circuit layer which are laminated is not more than 30 microns. Furthermore, in addition to manufacturing circuits on the circuit layer 20 according to the circuit design, an insulating layer (not shown) can be further disposed and/or a related metal surface processing can be performed.

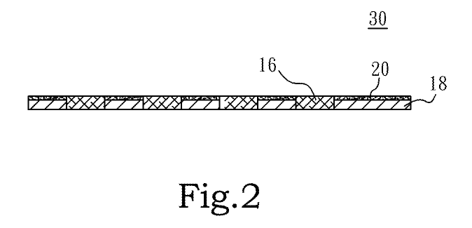

Continued with the above-mentioned descriptions, the thinning process of the metal plate 10 may be performed on the metal plate 10 in a chemical or mechanical manner. According to the layout of the electronic elements on the circuit layer 20, the entire thickness of the heat conducting substrate structure 30 is adjusted by thinning the metal plate 10. In another embodiment, as shown in FIG. 2, the metal plate 10 (shown in FIG. 1d) may be thinned completely, so that only the micro bumps 16 are remained. That is, the metal plate 10 below the adhesive layer 18 is thinned completely, so that only the metal micro bumps 16 between the adhesive layer 18 and the circuit layer 20 are remained.

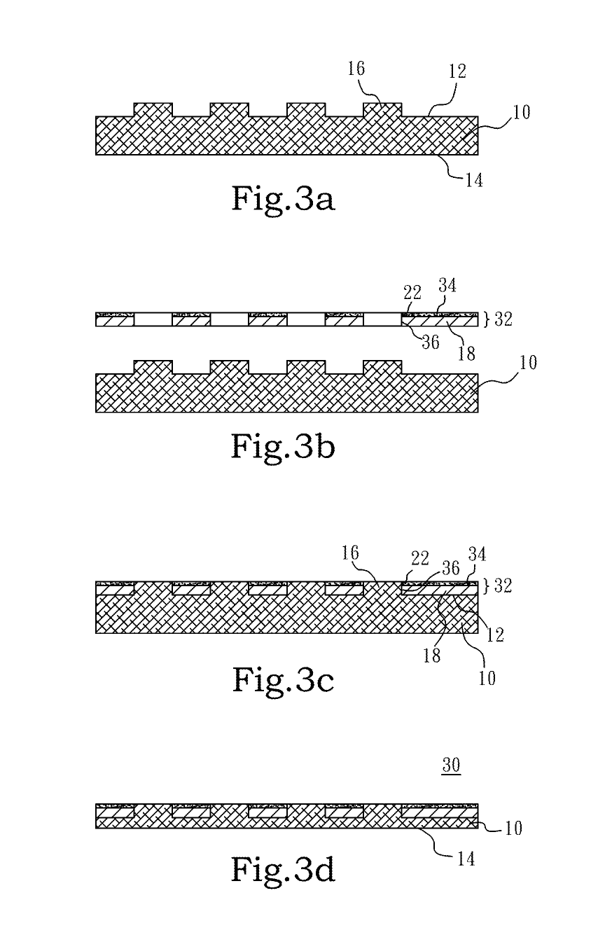

Referring to FIG. 3a through FIG. 3d, FIG. 3a through FIG. 3d show structural schematic views of a method for manufacturing a heat conducting substrate of a second embodiment of the present invention. As shown in FIG. 3a, a metal plate 10 is provided, which has a first surface 12 and an opposed second surface 14. A plurality of micro bumps 16 are formed on the first surface 12. As shown in FIG. 3b, a resin-coated copper (RCC) is provided, which comprises a copper layer 34 and an adhesive layer 18 disposed on the back surface of the copper layer 34. A plurality of first openings 22 are formed on the copper layer 34, and a plurality of second openings 36 are formed on the adhesive layer 18. The first openings 22 and the second openings 36 pass through the copper layer 34 and the adhesive layer 18 respectively, so as to correspond to each other. Then, as shown in FIG. 3c, the pass-through first openings 22 and second openings 36 are aligned with the micro bumps 16 of the metal plate 10, the resin-coated copper 32 is fixed directly on the first surface 12 of the metal plate 10 by the adhesive layer 18, and the micro bumps 16 pass through the second openings 36 and the first openings 22 to be exposed. In one embodiment, top surfaces 161 of the micro bumps 16 are flush with a surface of the copper layer 34. Then, circuits are manufactured on the copper layer 34 (not shown). Then, as shown in FIG. 3d, the metal plate 10 is thinned from the second surface 14 of the metal plate 10. As such, a heat conducting substrate structure 30 is completed.

In the second embodiment, the first openings 22 of the copper layer 34 of the resin-coated copper 32 and the second openings 36 of the adhesive layer 18 may be formed integrally, so that positions thereof correspond to positions of the micro bumps 16 of the metal plate 10. Furthermore, the metal plate 10 below the resin-coated copper 32 may be thinned completely as well, so that only the micro bumps 16 are remained. That is, the metal plate 10 below the adhesive layer 18 is thinned completely, so that only the metal micro bumps 16 between the adhesive layer 18 and the copper layer 34 are remained.

In the present invention, the exposed micro bumps serve as paths for the electronic elements subsequently disposed on the circuit layer to dissipate heat to other elements. In the present invention, a thinnest total thickness of the heat conducting substrate can be no more than 30 microns, so as to meet the requirements of being thin-shaped and having high heat conducting electronic elements. On the other hand, the present invention performs the adhering and circuit machining processes on a thicker metal plate first, and then performs the thinning process to meet the requirements of the electronic elements, so that a prior-art drawback, i.e., a decreased yield, which is resulted from that a thickness of the circuit board is too thin to perform circuit manufacturing, can be avoided.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. A method for manufacturing a heat conducting substrate, comprising:
providing a metal plate with a first surface and an opposed second surface;
forming a plurality of micro bumps on the first surface;
disposing an adhesive layer on the first surface among the micro bumps;
providing a circuit layer with a plurality of first openings formed thereon, positions of the first openings corresponding to positions of the micro bumps;
fixing the circuit layer onto the adhesive layer, wherein the micro bumps are exposed through the first openings respectively; and
manufacturing circuits on the circuit layer.

2. The method for manufacturing a heat conducting substrate according to claim 1, further comprising a thinning process which is performed on the metal plate from the second surface.

3. The method for manufacturing a heat conducting substrate according to claim 2, wherein the metal plate is thinned completely so that only the micro bumps are remained.

4. The method for manufacturing a heat conducting substrate according to claim 2, wherein the metal plate is thinned in a chemical or mechanical manner.

5. The method for manufacturing a heat conducting substrate according to claim 1, wherein the circuit layer is a copper layer.

6. The method for manufacturing a heat conducting substrate according to claim 5, wherein the adhesive layer and the copper layer are fixed together to be a resin-coated copper (RCC), and a plurality of second openings, which correspond to the first openings respectively, are formed on the adhesive layer, wherein the resin-coated copper is fixed to the first surface of the metal plate by the adhesive layer thereof, and the micro bumps pass through the second openings and the first openings to be exposed.

7. The method for manufacturing a heat conducting substrate according to claim 6, wherein the first openings and the second openings are formed integrally.

8. The method for manufacturing a heat conducting substrate according to claim 1, wherein the adhesive layer and the circuit layer are fixed together in a lamination or compression molding manner.

9. The method for manufacturing a heat conducting substrate according to claim 1, wherein a total thickness of the metal plate, the adhesive layer and the circuit layer which are laminated is not more than 30 microns.

10. The method for manufacturing a heat conducting substrate according to claim 1, wherein a top surface of the micro bump is flush with a surface of the circuit layer.
